(19) United States
(12) Patent Application Publication
(10) Pub. No.: US 2017/0271563 A1
(43) Pub. Date: Sep. 21, 2017

(54) METHOD AND APPARATUS FOR CONTROLLED SEMICONDUCTOR GROWTH DURING SYNTHESIS OF QUANTUM DOT MATERIALS

(71) Applicants: Chris Durgan, Portland, OR (US); Matthew Bertram, Portland, OR (US); Matthew J. Carillo, Portland, OR (US); Paul Archer, Portland, OR (US)

(72) Inventors: Chris Durgan, Portland, OR (US); Matthew Bertram, Portland, OR (US); Matthew J. Carillo, Portland, OR (US); Paul Archer, Portland, OR (US)

(21) Appl. No.: 15/458,882

(22) Filed: Mar. 14, 2017

Related U.S. Application Data
(60) Provisional application No. 62/308,765, filed on Mar. 15, 2016.

(51) Int. Cl. H01L 33/50; C09K 11/88; C09K 11/02

(52) U.S. Cl. CPC H01L 33/502; C09K 11/025; C09K 11/883; B82Y 40/00

(57) ABSTRACT

Techniques and mechanisms for synthesizing quantum dot structures. In an embodiment, a first reaction is performed to dissolve a precursor of a semiconductor material, wherein water is created as a by-product of the first reaction. Some or all of the water is removed and another chemical compound is added, wherein the chemical compound is a primary alcohol or a 1,2-diol. After the addition of the chemical compound, a second reaction is performed to grow at least some nanocrystalline portion of the quantum dot. In another embodiment, the chemical compound is 1,2-hexanediol, 1,2-dodecanediol or 1-octadecanol.

### CROSS-REFERENCE TO RELATED APPLICATIONS

This application claims the benefit of U.S. Provisional Application No. 62/308,765, filed Mar. 15, 2016, the entire contents of which are hereby incorporated by reference herein.

### BACKGROUND

1. Technical Field

Embodiments of the present invention are in the field of quantum dots for light emitting diodes (LEDs) and other applications and more particularly, but not exclusively, to techniques for controlling the growth of quantum dot (QD) structures.

2. Background Art

Quantum dots having a high photoluminescence quantum yield (PLQY) may be applicable as down-converting materials in down-converting nanocomposites used in solid state lighting applications. Down-converting materials are used to improve the performance, efficiency and color choice in lighting applications, particularly light emitting diodes (LEDs). In such applications, quantum dots absorb light of a particular first (available or selected) wavelength, usually blue, and then emit light at a second wavelength, usually red or green.

### BRIEF DESCRIPTION OF THE DRAWINGS

The various embodiments of the present invention are illustrated by way of example, and not by way of limitation, in the figures of the accompanying drawings and in which:

FIG. 1 illustrates a schematic of a cross-sectional view of a quantum dot, in accordance with an embodiment.

FIG. 2 is a flow diagram illustrating elements of a method to synthesize quantum dot structures according to an embodiment.

FIGS. 3A-3D each show images illustrating quantum dot structures variously formed by respective processes each according to a corresponding embodiment.

FIG. 4 shows a graph which includes plots of emission spectra for respective quantum dots each according to a corresponding embodiment.

FIG. 5 illustrates operations to synthesize quantum dot structures in accordance with an embodiment.

FIG. 6 illustrates a lighting device that includes a blue LED with a layer having a polymer matrix with a dispersion of quantum dots in accordance with an embodiment.

FIG. 7 illustrates a cross-sectional view of a lighting device with a layer having a polymer matrix with a dispersion of quantum dots in accordance with an embodiment.

FIG. 8 illustrates a cross-sectional view of a lighting device with a layer having a polymer matrix with a dispersion of quantum dots in accordance with another embodiment.

FIG. 9 illustrates a cross-sectional view of a lighting device with a layer having a polymer matrix with a dispersion of quantum dots in accordance with another embodiment.

FIG. 10 illustrates a cross-sectional view of a lighting device with a layer having a polymer matrix with a dispersion of quantum dots in accordance with another embodiment.

FIGS. 11A-11C illustrate cross-sectional views of various configurations for lighting devices each with a respective dispersion of quantum dots in accordance with a corresponding embodiment.

### DETAILED DESCRIPTION

Embodiments described herein variously include techniques and/or mechanisms to provide a chemical substitute for water during the synthesis of quantum dot (or “QD”) structures—e.g., where the chemical substitute is to promote a controlled growth of nanocrystals. For some chemical reactions used to synthesize quantum dot structures, the presence of water which has been generated as a reaction byproduct (also referred to herein as “native water”) can promote later quantum dot growth. Native water may result from chemical processes which, for example, prepares a solution to be used in the formation of at least a portion of a quantum dot—e.g., an inner portion of a quantum dot (referred to herein as a “seed” or “core”) or an outer “shell” portion disposed around the inner portion.

Such native water can be inconsistently distributed over a reaction area and/or over time during quantum dot growth—e.g., due to at least some native water uncontrollably leaving a reaction chamber or condensing on the reaction chamber's interior. Inconsistent water distribution can result in variation in quantum dot growth, preventing or otherwise mitigating the controlled formation of quantum dots which are to have a certain desired size and/or shape (e.g., including a particular geometry, aspect ratio, etc.).

Furthermore, it may be difficult to remove native water in a consistent way which is repeatable from batch to batch. Due to its nature as a byproduct of the reaction chemistry (e.g., due to its low boiling point relative to reaction temperatures), the amount of native water available in a reactor cannot be easily adjusted to affect growth rates. As a result, the amount of native water available to drive quantum dot growth typically varies on a batch-to-batch basis as well, thus causing variation between different batches in the growth of quantum dot structures. For at least these reasons, some quantum dot features (e.g., including particle size, size distribution and/or shape) have, to date, been highly susceptible to variation in the presence, or absence, of native water. In turn, various operational characteristics of quantum dot structures—such as emission wavelength and quantum yield—may be impacted by the presence (or absence) of native water during fabrication processes.

In some embodiments, water is generated in a reaction chamber as a by-product of a chemical process to provide a solution used in quantum dot growth. Some or all such water may be removed from the chamber, where another chemical compound is then added to the chamber to facilitate growth of at least a portion of a quantum dot. The chemical compound may, for example, include a primary alcohol or a 1,2-diol. As used herein, “primary alcohol” refers to an alcohol which has a primary carbon atom and hydroxyl group (—OH) bonded thereto. The term “diol” refers herein to any of a variety of chemical compounds containing two hydroxyl groups. A “1,2-diol” may be any of a variety of diols which have two hydroxyl groups each bonded to a respective one of two carbon (C) atoms which adjoin each other in a chain or ring of carbon atoms.

Some embodiments described herein are not limited to a particular shape or size of a quantum dot. For example, a quantum dot formed by processing according to some embodiments may have any of a variety of shapes including, but not limited to, a sphere, rod, tetrapod, triangle, teardrop, sheet, etc. Alternatively or in addition, such a quantum dot may be formed of a single material or multiple materials—e.g., in a core/shell/optional shell/optional shell configuration or an alloyed composition.

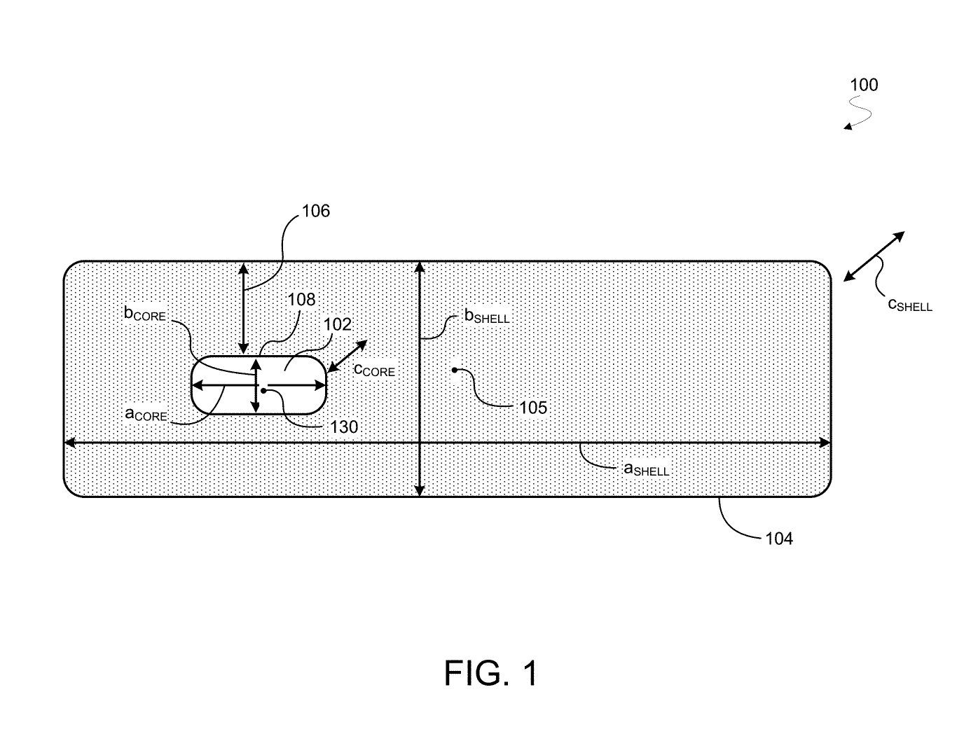

FIG. 1 shows a semiconductor structure 100 which is formed by chemical reaction processes according to an embodiment. Semiconductor structure 100 is one example of an embodiment wherein at least a portion of a quantum dot structure includes, or has disposed thereon, a residue which results from fabrication processes such as those described herein. The residue may be a chemical compound—e.g., including a primary alcohol or a 1,2-diol—which is introduced, as a substitute for native water, to promote nanocrystalline growth while facilitating a controlled formation of quantum dot sizes and/or shapes. Alternatively, the residue may be a product of a reaction involving such a chemical compound (i.e., a reaction involving a primary alcohol or a 1,2-diol).

The core and shell components of semiconductor structure 100—e.g., including their scale relative to each other, their locations relative to each other, etc.—are merely illustrative of some embodiments. Other embodiments may provide a semiconductor structure having more, fewer and/or differently configured structural components—e.g., wherein at least of the portion of such a semiconductor structure has disposed therein or thereon a residue of a chemical compound including a primary alcohol or a 1,2-diol.

As a reference, FIG. 1 illustrates a schematic of a cross-sectional view of a quantum dot, in accordance with an embodiment. Referring to FIG. 1, a semiconductor structure (e.g., a quantum dot structure) 100 includes a nanocrystalline core 102 surrounded by a nanocrystalline shell 104. The nanocrystalline core 102 has a length axis (a_{CORE}), a width axis (b_{CORE}) and a depth axis (c_{CORE}), the depth axis provided into and out of the plane shown in FIG. 1. Likewise, the nanocrystalline shell 104 has a length axis (a_{SHELL}), a width axis (b_{SHELL}) and a depth axis (c_{SHELL}), the depth axis provided into and out of the plane shown in FIG. 1. The nanocrystalline core 102 has a center 130 and the nanocrystalline shell 104 has a center 105. The nanocrystalline shell 104 surrounds the nanocrystalline core 102 in the b-axis direction by an amount 106, as is also depicted in FIG. 1.

In an embodiment, a portion of semiconductor structure 100—e.g., including at least a portion of nanocrystalline shell 104 and, in some embodiments, at least a portion of nanocrystalline core 102—has disposed therein or thereon a residual amount of a primary alcohol or a 1,2-diol (as illustrated by the shading of nanocrystalline shell 104). By way of illustration and not limitation, one or more nanocrystals of shell 104 may comprise unit cells, wherein an amount of the residual chemical compound (e.g., including a primary alcohol or a 1,2-diol) is at least 10 parts per million (ppm) of the nanocrystals' unit cells. The amount of residue disposed in or on shell 104 (or another such portion of a quantum dot) may, for example, be in a range of 10 ppm to 500 ppm (e.g., in a range of 30 ppm to 100 ppm, in some embodiments). In some embodiments, the residue may be a product of a reaction involving such a primary alcohol or 1,2-diol.

The following are attributes of a quantum dot that may be tuned for optimization, with reference to the parameters provided in FIG. 1, in accordance with some embodiments. Nanocrystalline core 102 diameter (a, b or c) and aspect ratio (e.g., a/b) can be controlled for rough tuning for emission wavelength (a higher value for either providing increasingly red emission). A smaller overall nanocrystalline core provides a greater surface to volume ratio. The width of the nanocrystalline shell along 106 may be tuned for yield optimization and quantum confinement providing approaches to control red-shifting and mitigation of surface effects. However, strain considerations must be accounted for when optimizing the value of thickness 106. The length (a_{SHELL}) of the shell is tunable to provide longer radiative decay times as well as increased light absorption. The overall aspect ratio of the structure 100 (e.g., the greater of a_{SHELL}/b_{SHELL} and a_{SHELL}/c_{SHELL}) may be tuned to directly impact photoluminescence quantum yield (PLQY). Meanwhile, overall surface/volume ratio for 100 may be kept relatively smaller to provide lower surface defects, provide higher photoluminescence, and limit self-absorption. Referring again to FIG. 1, the shell/core interface 108 may be tailored to avoid dislocations and strain sites. In one such embodiment, a high quality interface is obtained by tailoring one or more of injection temperature and mixing parameters, the use of surfactants, and control of the reactivity of precursors, as is described in greater detail below.

In accordance with some embodiments, a high PLQY quantum dot is based on a core/shell pairing using an anisotropic core. With reference to FIG. 1, an anisotropic core is a core having one of the axes a_{CORE}, b_{CORE} or c_{CORE} different from one or both of the remaining axes. An aspect ratio of such an anisotropic core is determined by the longest of the axes a_{CORE}, b_{CORE} or c_{CORE} divided by the shortest of the axes a_{CORE}, b_{CORE} or c_{CORE} to provide a number greater than 1 (an isotropic core has an aspect ratio of 1). It is to be understood that the outer surface of an anisotropic core may have rounded or curved edges (e.g., as in an ellipsoid) or may be faceted (e.g., as in a stretched or elongated tetragonal or hexagonal prism) to provide an aspect ratio of greater than 1 (note that a sphere, a tetragonal prism, and a hexagonal prism are all considered to have an aspect ratio of 1 in keeping with various embodiments).

A workable range of aspect ratio for an anisotropic nanocrystalline core for a quantum dot may be selected for maximization of PLQY. For example, a core essentially isotropic may not provide advantages for increasing PLQY, while a core with too great an aspect ratio (e.g., 2 or greater) may present challenges synthetically and geometrically when forming a surrounding shell. Furthermore, embedding the core in a shell composed of a material different than the core may also be used enhance PLQY of a resulting quantum dot.

Accordingly, in an embodiment, a semiconductor structure includes an anisotropic nanocrystalline core composed of a first semiconductor material and having an aspect ratio between, but not including, 1.0 and 2.0. The semiconductor structure also includes a nanocrystalline shell composed of a second, different, semiconductor material at least partially surrounding the anisotropic nanocrystalline core. In one such embodiment, the aspect ratio of the anisotropic nanocrystalline core is approximately in the range of 1.01-1.2 and, in a particular embodiment, is approximately in the range of 1.1-1.2. In the case of rounded edges, then, the nanocrystalline core may be substantially, but not perfectly, spherical. However, the nanocrystalline core may instead be faceted. In an embodiment, the anisotropic nanocrystalline core is disposed in an asymmetric orientation with respect to the nanocrystalline shell, as described in greater detail in the example below.

Another consideration for maximization of PLQY in a quantum dot structure is to provide an asymmetric orientation of the core within a surrounding shell. For example, referring again to FIG. 1, the center 130 of the core 102 may be misaligned with (e.g., have a different spatial point than) the center 105 of the shell 102. In an embodiment, a semiconductor structure includes an anisotropic nanocrystalline core composed of a first semiconductor material. The semiconductor structure also includes a nanocrystalline shell composed of a second, different, semiconductor material at least partially surrounding the anisotropic nanocrystalline core. The anisotropic nanocrystalline core is disposed in an asymmetric orientation with respect to the nanocrystalline shell. In one such embodiment, the nanocrystalline shell has a long axis (e.g., a_{SHELL}), and the anisotropic nanocrystalline core is disposed off-center along the long axis. In another such embodiment, the nanocrystalline shell has a short axis (e.g., b_{SHELL}), and the anisotropic nanocrystalline core is disposed off-center along the short axis. In yet another embodiment, however, the nanocrystalline shell has a long axis (e.g., a_{SHELL}) and a short axis (e.g., b_{SHELL}), and the anisotropic nanocrystalline core is disposed off-center along both the long and short axes.

With reference to the above described nanocrystalline core and nanocrystalline shell pairings, in an embodiment, the nanocrystalline shell completely surrounds the anisotropic nanocrystalline core. In an alternative embodiment, however, the nanocrystalline shell only partially surrounds the anisotropic nanocrystalline core, exposing a portion of the anisotropic nanocrystalline core, e.g., as in a tetrapod geometry or arrangement. In an embodiment, the nanocrystalline shell is an anisotropic nanocrystalline shell, such as a nano-rod, that surrounds the anisotropic nanocrystalline core at an interface between the anisotropic nanocrystalline shell and the anisotropic nanocrystalline core. The anisotropic nanocrystalline shell passivates or reduces trap states at the interface. The anisotropic nanocrystalline shell may also, or instead, deactivate trap states at the interface.

With reference again to the above described nanocrystalline core and nanocrystalline shell pairings, in an embodiment, the first and second semiconductor materials (core and shell, respectively) are each materials such as, but not limited to, Group II-VI materials, Group III-V materials, Group IV-VI materials, Group materials, or Group II-IV-VI materials and, in one embodiment, are monocrystalline. In one such embodiment, the first and second semiconductor materials are both Group II-VI materials, the first semiconductor material is cadmium selenide (CdSe), and the second semiconductor material is one such as, but not limited to, cadmium sulfide (CdS), zinc sulfide (ZnS), or zinc selenide (ZnSe). In an embodiment, the semiconductor structure further includes a nanocrystalline outer shell at least partially surrounding the nanocrystalline shell and, in one embodiment, the nanocrystalline outer shell completely surrounds the nanocrystalline shell. The nanocrystalline outer shell is composed of a third semiconductor material different from the first and second semiconductor materials. In a particular such embodiment, the first semiconductor material is cadmium selenide (CdSe), the second semiconductor material is cadmium sulfide (CdS), and the third semiconductor material is zinc sulfide (ZnS).

With reference again to the above described nanocrystalline core and nanocrystalline shell pairings, in an embodiment, the semiconductor structure (i.e., the core/shell pairing in total) has an aspect ratio approximately in the range of 1.5-10 and, 3-6 in a particular embodiment. In an embodiment, the nanocrystalline shell has a long axis and a short axis. The long axis has a length approximately in the range of 5-40 nanometers. The short axis has a length approximately in the range of 1-5 nanometers greater than a diameter of the anisotropic nanocrystalline core parallel with the short axis of the nanocrystalline shell. In a specific such embodiment, the anisotropic nanocrystalline core has a diameter approximately in the range of 2-5 nanometers. In another embodiment, the anisotropic nanocrystalline core has a diameter approximately in the range of 2-5 nanometers. The thickness of the nanocrystalline shell on the anisotropic nanocrystalline core along a short axis of the nanocrystalline shell is approximately in the range of 1-5 nanometers of the second semiconductor material.

With reference again to the above described nanocrystalline core and nanocrystalline shell pairings, in an embodiment, the anisotropic nanocrystalline core and the nanocrystalline shell form a quantum dot. In one such embodiment, the quantum dot has a photoluminescence quantum yield (PLQY) of at least 90%. Emission from the quantum dot may be mostly, or entirely, from the nanocrystalline core. For example, in an embodiment, emission from the anisotropic nanocrystalline core is at least approximately 75% of the total emission from the quantum dot. An absorption spectrum and an emission spectrum of the quantum dot may be essentially non-overlapping. For example, in an embodiment, an absorbance ratio of the quantum dot based on absorbance at 400 nanometers versus absorbance at an exciton peak for the quantum dot is approximately in the range of 5-35.

In an embodiment, a quantum dot based on the above described nanocrystalline core and nanocrystalline shell pairings is a down-converting quantum dot. However, in an alternative embodiment, the quantum dot is an up-shifting quantum dot. In either case, a lighting apparatus may include a light emitting diode and a plurality of quantum dots such as those described above. The quantum dots may be applied proximal to the LED and provide down-conversion or up-shifting of light emitted from the LED. Thus, semiconductor structures according to some embodiments may be advantageously used in solid state lighting. The visible spectrum includes light of different colors having wavelengths between about 380 nm and about 780 nm that are visible to the human eye. An LED will emit a UV or blue light which is down-converted (or up-shifted) by semiconductor structures described herein. Any suitable ratio of color semiconductor structures may be used in devices of various embodiments. LED devices according to some embodiments may have incorporated therein sufficient quantity of semiconductor structures (e.g., quantum dots) described herein capable of down-converting any available blue light to red, green, yellow, orange, blue, indigo, violet or other color.

Semiconductor structures according to some embodiments may be advantageously used in biological imaging in, e.g., one or more of the following environments: fluorescence resonance energy transfer (FRET) analysis, gene technology, fluorescent labeling of cellular proteins, cell tracking, pathogen and toxin detection, in vivo animal imaging or tumor biology investigation. Accordingly, some embodiments contemplate probes having quantum dots described herein.

Semiconductor structures according to some embodiments may be advantageously used in photovoltaic cells in layers where high PLQY is important. Accordingly, some embodiments contemplate photovoltaic devices using quantum dots described herein.

There are various synthetic approaches for fabricating CdSe quantum dots. For example, in an embodiment, under an inert atmosphere (e.g., ultra high purity (UHP) argon), cadmium oxide (CdO) is dissociated in the presence of surfactant (e.g., octadecylphosphonic acid (ODPA)) and solvent (e.g., trioctylphopshine oxide (TOPO); trioctylphosphine (TOP)) at high temperatures (e.g., 350-380 degrees Celsius). Resulting Cd²⁺ cations are exposed by rapid injection to solvated selenium anions (Se²⁻), resulting in a nucleation event forming small CdSe seeds. The seeds continue to grow, feeding off of the remaining Cd²⁺ and Se²⁻ available in solution, with the resulting quantum dots being stabilized by surface interactions with the surfactant in solution (ODPA). The aspect ratio of the CdSe seeds is typically between 1 and 2, as dictated by the ratio of the ODPA to the Cd concentration in solution. The quality and final size of these cores is affected by several variables such as, but not limited to, reaction time, temperature, reagent concentration, surfactant concentration, moisture content in the reaction, or mixing rate. The reaction is targeted for a narrow size distribution of CdSe seeds (assessed by transmission electron microscopy (TEM)), typically a slightly cylindrical seed shape (also assessed by TEM) and CdSe seeds exhibiting solution stability over time (assessed by PLQY and scattering in solution).

For the cadmium sulfide (CdS) shell growth on the CdSe seeds, or nanocrystalline cores, under an inert atmosphere (e.g. UHP argon), cadmium oxide (CdO) is dissociated in the presence of surfactants (e.g., ODPA and hexylphosphonic acid (HPA)) and solvent (e.g. TOPO and/or TOP) at high temperatures (e.g., 350-380 degrees Celsius). The resulting Cd²⁺ cations in solution are exposed by rapid injection to solvated sulfur anions (S²⁻) and CdSe cores. Immediate growth of the CdS shell around the CdSe core occurs. The use of both a short chain and long chain phosphonic acid promotes enhanced growth rate at along the c-axis of the structure, and slower growth along the a-axis, resulting in a rod-shaped core/shell nanomaterial.

CdSe/CdS core-shell quantum dots have been shown in the literature to exhibit respectable quantum yields (e.g., 70-75%). However, the persistence of surface trap states (which decrease overall photoluminescent quantum yield) in these systems arises from a variety of factors such as, but not limited to, strain at the core-shell interface, high aspect ratios (ratio of rod length to rod width of the core/shell pairing) which lead to larger quantum dot surface area requiring passivation, or poor surface stabilization of the shell.

In order to address the above synthetic limitations on the quality of quantum dots formed under conventional synthetic procedures, in an embodiment, a multi-faceted approach is used to mitigate or eliminate sources of surface trap states in quantum dot materials. For example, lower reaction temperatures during the core/shell pairing growth yields slower growth at the CdSe—CdS interface, giving each material sufficient time to orient into the lowest-strain positions. Aspect ratios are controlled by changing the relative ratios of surfactants in solution as well as by controlling temperature. Increasing an ODPA/HPA ratio in reaction slows the rapid growth at the ends of the core/shell pairings by replacing the facile HPA surfactant with the more obstructive ODPA surfactant. In addition, lowered reaction temperatures are also used to contribute to slowed growth at the ends of the core/shell pairings. By controlling these variables, the aspect ratio of the core/shell pairing is optimized for quantum yield. In one such embodiment, following determination of optimal surfactant ratios, overall surfactant concentrations are adjusted to locate a PLQY maximum while maintaining long-term stability of the fabricated quantum dots in solution. Furthermore, in an embodiment, aspect ratios of the seed or core (e.g., as opposed to the seed/shell pairing) are limited to a range between, but not including 1.0 and 2.0 in order to provide an appropriate geometry for high quality shell growth thereon.

In another aspect, an additional or alternative strategy for improving the interface between CdSe and CdS includes, in an embodiment, chemically treating the surface of the CdSe cores prior to reaction. CdSe cores are stabilized by long chain surfactants (ODPA) prior to introduction into the CdS growth conditions. Reactive ligand exchange can be used to replace the ODPA surfactants with ligands which are easier to remove (e.g., primary or secondary amines), facilitating improved reaction between the CdSe core and the CdS growth reagents.

In addition to the above factors affecting PLQY in solution, self-absorption may negatively affect PLQY when these materials are cast into films. This phenomenon may occur when CdSe cores re-absorb light emitted by other quantum dots. In one embodiment, the thickness of the CdS shells around the same CdSe cores is increased in order to increase the amount of light absorbed per core/shell pairing, while keeping the particle concentration the same or lower in films including the quantum dot structures. The addition of more Cd and S to the shell formation reaction leads to more shell growth, while an optimal surfactant ratio allows targeting of a desired aspect ratio and solubility of the core/shell pairing.

Accordingly, in an embodiment, an overall method of fabricating a semiconductor structure, such as the above described quantum dot structures, includes forming an anisotropic nanocrystalline core from a first semiconductor material. A nanocrystalline shell is formed from a second, different, semiconductor material to at least partially surround the anisotropic nanocrystalline core. In one such embodiment, the anisotropic nanocrystalline core has an aspect ratio between, but not including, 1.0 and 2.0, as described above.

With reference to the above described general method for fabricating a nanocrystalline core and nanocrystalline shell pairing, in an embodiment, prior to forming the nanocrystalline shell, the anisotropic nanocrystalline core is stabilized in solution with a surfactant. In one such embodiment, the surfactant is octadecylphosphonic acid (ODPA). In another such embodiment, the surfactant acts as a ligand for the anisotropic nanocrystalline core. In that embodiment, the method further includes, prior to forming the nanocrystalline shell, replacing the surfactant ligand with a second ligand, the second ligand more labile than the surfactant ligand. In a specific such embodiment, the second ligand is one such as, but not limited to, a primary amine or a secondary amine.

With reference again to the above described general method for fabricating a nanocrystalline core and nanocrystalline shell pairing, in an embodiment, forming the nanocrystalline shell includes forming the second semiconductor material in the presence of a mixture of surfactants. In one such embodiment, the mixture of surfactants includes a mixture of octadecylphosphonic acid (ODPA) and hexylphosphonic acid (HPA). In a specific such embodiment, forming the nanocrystalline shell includes tuning the aspect ratio of the nanocrystalline shell by tuning the ratio of ODPA versus HPA. Forming the second semiconductor material in the presence of the mixture of surfactants may also, or instead, include using a solvent such as, but not limited to, trioctylphosphine oxide (TOPO) and trioctylphosphine (TOP).

With reference again to the above described general method for fabricating a nanocrystalline core and nanocrystalline shell pairing, in an embodiment, forming the anisotropic nanocrystalline core includes forming at a temperature approximately in the range of 350-380 degrees Celsius. In an embodiment, forming the anisotropic nanocrystalline core includes forming a cadmium selenide (CdSe) nanocrystal from cadmium oxide (CdO) and selenium (Se) in the presence of a surfactant at a temperature approximately in the range of 300-400 degrees Celsius. The reaction is arrested prior to completion. In one such embodiment, forming the nanocrystalline shell includes forming a cadmium sulfide (CdS) nanocrystalline layer on the CdSe nanocrystal from cadmium oxide (CdO) and sulfur (S) at a temperature approximately in the range of 120-380 degrees Celsius. That reaction is also arrested prior to completion.

The aspect ratio of the fabricated semiconductor structures may be controlled by one of several methods. For example, ligand exchange may be used to change the surfactants and/or ligands and alter the growth kinetics of the shell and thus the aspect ratio. Changing the core concentration during core/shell growth may also be exploited. An increase in core concentration and/or decrease concentration of surfactants results in lower aspect ratio core/shell pairings. Increasing the concentration of a shell material such as S for CdS will increase the rate of growth on the ends of the core/shell pairings, leading to longer, higher aspect ratio core/shell pairings.

As mentioned above, in one embodiment, nanocrystalline cores undergo a reactive ligand exchange which replaces core surfactants with ligands that are easier to remove (e.g., primary or secondary amines), facilitating better reaction between the CdSe core and the CdS growth reagents. In one embodiment, cores used herein have ligands bound or associated therewith. Attachment may be by dative bonding, Van der Waals forces, covalent bonding, ionic bonding or other force or bond, and combinations thereof. Ligands used with the cores may include one or more functional groups to bind to the surface of the nanocrystals. In a specific such embodiment, the ligands have a functional group with an affinity for a hydrophobic solvent.

In an embodiment, lower reaction temperatures during shell growth yields slower growth at the core/shell interface. While not wishing to be bound by any particular theory or principle it is believed that this method allows both core and shell seed crystals time to orient into their lowest-strain positions during growth. Growth at the ends of the core/shell pairing structure is facile and is primarily governed by the concentration of available precursors (e.g., for a shell of CdS this is Cd, S:TOP). Growth at the sides of the core/shell pairings is more strongly affected by the stabilizing ligands on the surface of the core/shell pairing. Ligands may exist in equilibrium between the reaction solution and the surface of the core/shell pairing structure. Lower reaction temperatures may tilt this equilibrium towards more ligands being on the surface, rendering it more difficult for growth precursors to access this surface. Hence, growth in the width direction is hindered by lower temperature, leading to higher aspect ratio core/shell pairings.

In general consideration of the above described semiconductor or quantum dot structures and methods of fabricating such semiconductor or quantum dot structures, in an embodiment, quantum dots are fabricated to have an absorbance in the blue or ultra-violet (V) regime, with an emission in the visible (e.g., red, orange, yellow, green, blue, indigo and violet, but particularly red and green) regime. The above described quantum dots may advantageously have a high PLQY with limited self-absorption, possess a narrow size distribution for cores, provide core stability over time (e.g., as assessed by PLQY and scattering in solution), and exhibit no major product loss during purification steps. Quantum dots fabricated according one or more of the above embodiments may have a decoupled absorption and emission regime, where the absorption is controlled by the shell and the emission is controlled by the core. In one such embodiment, the diameter of the core correlates with emission color, e.g., a core diameter progressing from 3-5.5 nanometers correlates approximately to a green→yellow→red emission progression.

With reference to the above described embodiments concerning semiconductor structures, such as quantum dots, and methods of fabricating such structures, the concept of a crystal defect, or mitigation thereof, may be implicated. For example, a crystal defect may form in, or be precluded from forming in, a nanocrystalline core or in a nanocrystalline shell, at an interface of the core/shell pairing, or at the surface of the core or shell. In an embodiment, a crystal defect is a departure from crystal symmetry caused by one or more of free surfaces, disorders, impurities, vacancies and interstitials, dislocations, lattice vibrations, or grain boundaries. Such a departure may be referred to as a structural defect or lattice defect. Reference to an exciton is to a mobile concentration of energy in a crystal formed by an excited electron and an associated hole. An exciton peak is defined as the peak in an absorption spectrum correlating to the minimum energy for a ground state electron to cross the band gap. The core/shell quantum dot absorption spectrum appears as a series of overlapping peaks that get larger at shorter wavelengths. Because of their discrete electron energy levels, each peak corresponds to an energy transition between discrete electron-hole (exciton) energy levels. The quantum dots do not absorb light that has a wavelength longer than that of the first exciton peak, also referred to as the absorption onset. The wavelength of the first exciton peak, and all subsequent peaks, is a function of the composition and size of the quantum dot. An absorbance ratio is absorbance of the core/shell nanocrystal at 400 nm divided by the absorbance of the core/shell nanocrystal at the first exciton peak. Photoluminescence quantum yield (PLQY) is defined as the ratio of the number of photons emitted to the number of photons absorbed. Core/shell pairing described herein may have a Type 1 band alignment, e.g., the core band gap is nested within the band gap of the shell. Emission wavelength may be determined by controlling the size and shape of the core nanocrystal, which controls the band gap of the core. Emission wavelength may also be engineered by controlling the size and shape of the shell. In an embodiment, the amount/volume of shell material is much greater than that of the core material. Consequently, the absorption onset wavelength is mainly controlled by the shell band gap. Core/shell quantum dots in accordance with some embodiments have an electron-hole pair generated in the shell which is then funneled into the core, resulting in recombination and emission from the core quantum dot. Preferably emission is substantially from the core of the quantum dot.

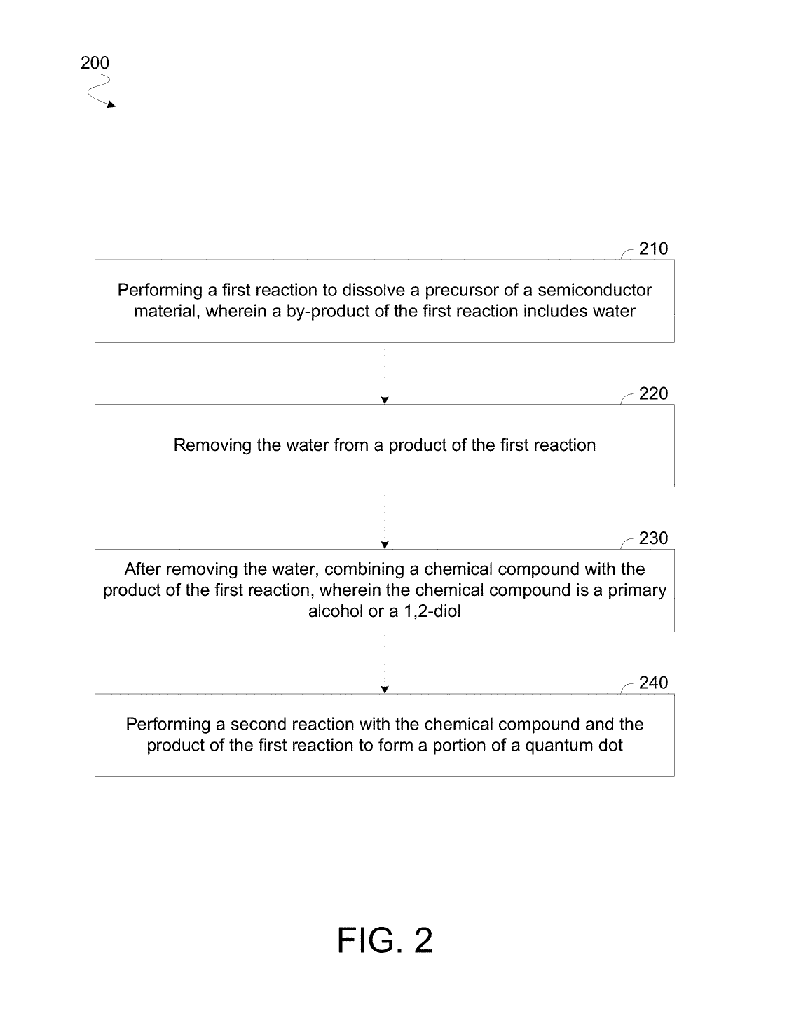

FIG. 2 shows operations of a method 200 to synthesize quantum dot structures according to an embodiment. Method 200 is one example of an embodiment to synthesize one or more quantum dots using a chemical compound which promotes a controlled nanocrystalline growth. Such one or more quantum dots may, for example, have some or all of the features described herein with reference to semiconductor structure 100.

Method 200 may comprise, at 210, performing a first reaction to dissolve a precursor of a semiconductor material, wherein a by-product of the first reaction includes water. By way of illustration and not limitation, the first reaction performed in 210 may dissolve a cadmium precursor cadmium oxide (CdO) to create Cd²⁺ ions, where water is generated as a by-product of such CdO dissolution. In other embodiments, method 200 further comprises, at 220, removing from a product of the first reaction some or all of the water which the first reaction created as a by-product. Such native water may, for example, be removed at 220 by an application of a vacuum to a reaction chamber in which first reaction takes place.

Method 200 may further comprise, at 230, combining a chemical compound with the product of the first reaction after the water is removed at 220, wherein the chemical compound is a primary alcohol or a 1,2-diol. A molecule of the 1,2-diol may, for example, include six or more carbon atoms which are arranged in a chain or a ring. By way of illustration and not limitation, the 1,2-diol may be 1,2-hexanediol or 1,2-dodecanediol. In some embodiments, a primary alcohol of the chemical compound includes 1-octadecanol. In some embodiments, method 200 further includes, at 240, performing a second reaction with the chemical compound to form a portion of a quantum dot. The second reaction may include a nanocrystalline growth that, for example, is to form an outer portion of nanocrystalline core 102 or some or all of nanocrystalline shell 104. The chemical compound may be added before or during such nanocrystalline growth, in various embodiments. Use of the chemical compound may, for example, facilitate a controlled tuning of anisotropic II-VI rods seeded by II-VI cores—e.g., wherein the aspect ratio of a quantum dot can be varied between 1.1:1 to 12:1 based on the chemical compound used, the concentration thereof, the duration of the reaction and/or the like.

The second reaction at 220 may be performed to variously grow nanocrystalline structures of one or more quantum dots. Such nanocrystalline structures may, for example, include any of a variety of II-VI semiconductor compounds, III-V semiconductor compounds, IV-IV semiconductor compounds and semiconductor compounds, including any of various alloys of such compounds. By way of illustration and not limitation, a quantum dot synthesized according to some embodiments may include a nanocrystal of one of zinc oxide (ZnO), zinc sulfide (ZnS), zinc selenide (ZnSe), zinc telluride (ZnTe), cadmium oxide (CdO), cadmium sulfide (CdS), cadmium selenide (CdSe), cadmium telluride (CdTe), mercury sulfide (HgS), mercury selenide (HgSe), mercury telluride (HgTe), mercury oxide (HgO), aluminum nitride (AlN), aluminum phosphide (AlP), aluminum arsenide (AlAs), aluminium antimonide (AlSb), gallium nitride (GaN), gallium phosphide (GaP), gallium arsenide (GaAs), gallium antimonide (GaSb), gallium selenide (GaSe), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe), magnesium oxide (MgO), magnesium sulfide (MgS), magnesium selenide (MgSe), or alloys thereof or mixtures thereof.

Method 200 may result in a portion of the quantum dot having disposed therein or thereon a residual amount of the chemical compound which is provided at 230 (or a residual amount of a product formed by a reaction involving the chemical compound)—e.g., wherein an amount of the residue is at least 10 ppm, relative to unit cells of the portion. In some embodiments, any residual amount of the chemical compound that may be disposed in one portion (e.g., a core) of a quantum dot may, for example, be less than the residual amount of the chemical compound which is in or on a second portion (e.g., a shell structure).

A chemical substitute for water may be used, for example, to promote growth of binary or alloyed cadmium sulfide (CdS) anisotropic quantum rods, seeded by binary or alloyed cadmium selenide (CdSe), or cores. In an illustrative scenario according to one embodiment, cadmium sulfide (CdS) shell structures may be variously grown on cadmium selenide (CdSe) seeds (or other such nanocrystalline cores) under an inert atmosphere such as ultra-high purity argon. In such an embodiment, cadmium oxide (CdO) may be dissociated in the presence of a surfactant, such as octadecylphosphonic acid or hexylphosphonic acid, and a solvent such as trioctylphosphine oxide or trioctylphosphine, at a high temperatures (e.g., 300° C.-380° C.). The product of such a reaction may subsequently be exposed to a vacuum to remove the evolved native water. A replacement compound is then introduced, and resulting Cd²⁺ cations in solution are exposed by rapid injection to solvated sulfur anions (S²⁻) and cadmium selenide (CdSe) cores. A growth of cadmium sulfide (CdS) shells around the cadmium selenide (CdSe) core may then occur. The use of both a short chain and long chain phosphonic acid may promote an enhanced growth rate at along a c-axis of the QD structure, and a slower growth rate along an a-axis, resulting in a rod-shaped core/shell nanomaterial.

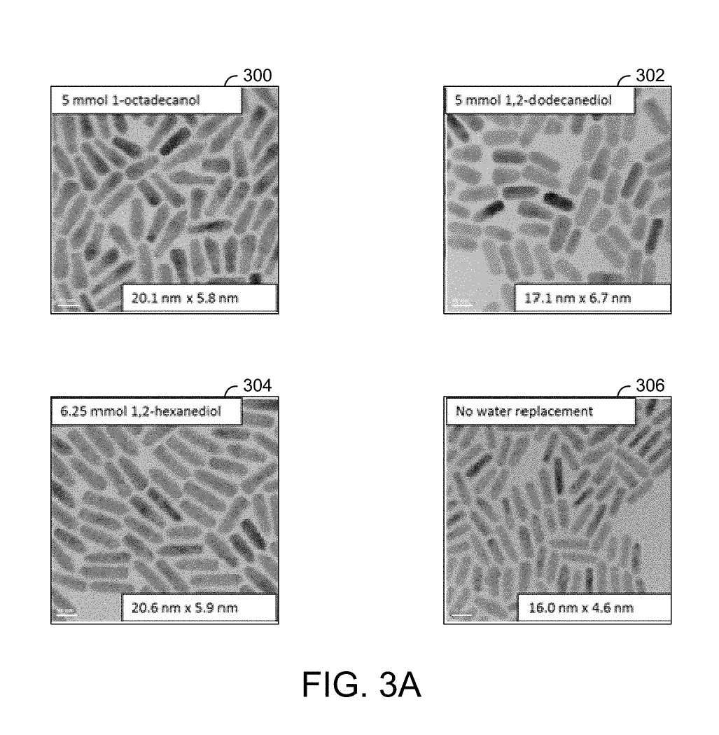

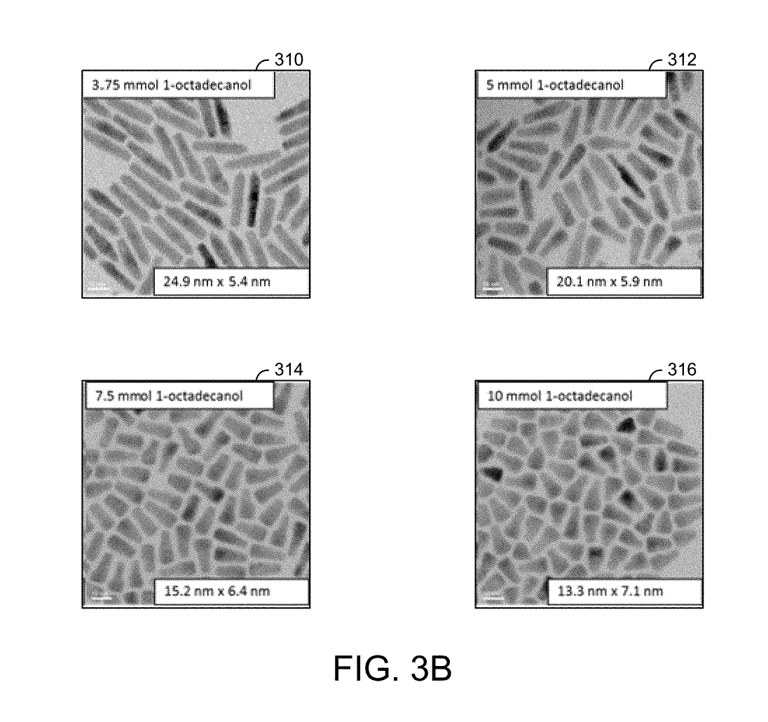

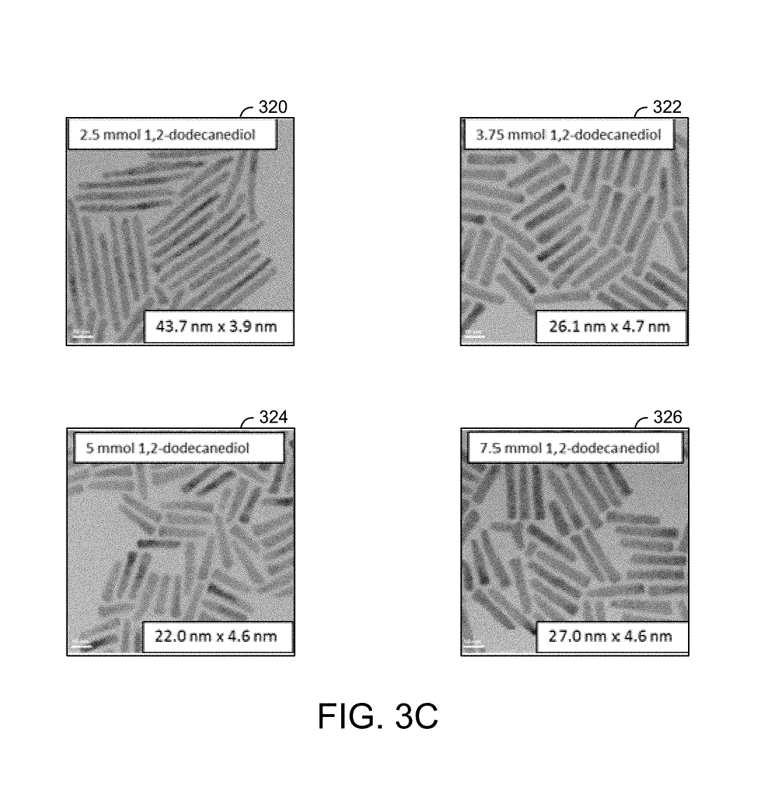

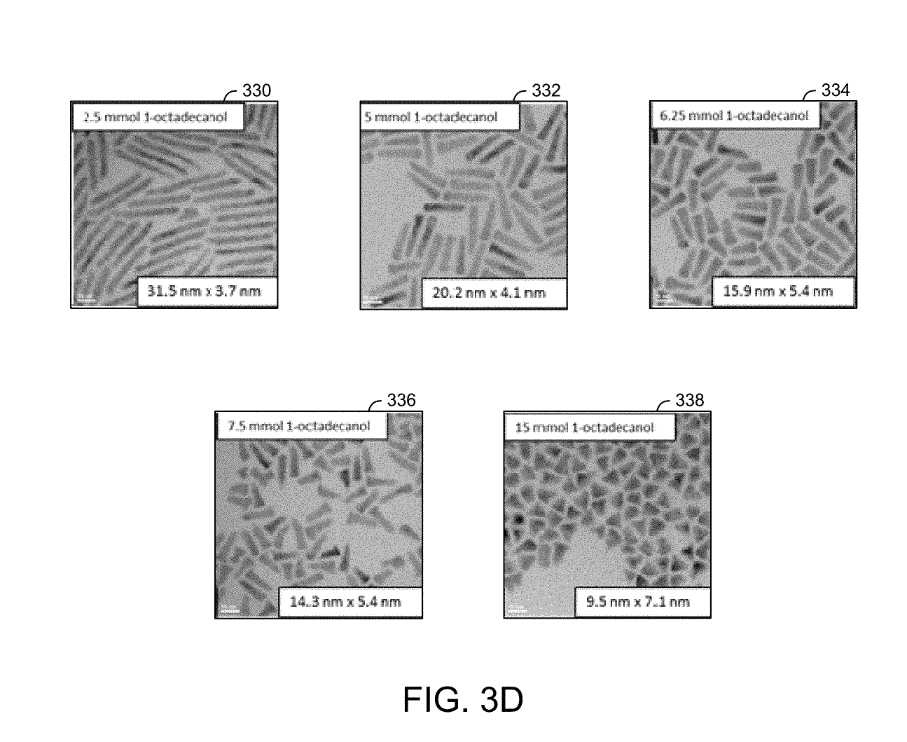

FIG. 3A shows transmission electron microscope (TEM) images 300, 302, 304 which variously represent respective quantum dot structures each formed by a chemical reaction according to a corresponding embodiment. Images 300, 302, 304 each show a result of a corresponding 90-minute reaction to grow CdS rods over CdSe cores, where such growth is in the presence of a respective one of a primary alcohol and a 1,2-diol. More particularly, the chemical reactions corresponding to image 300, 302, 304 use, respectively, 5 millimol (mmol) 1-octadecanol, 5 mmol 1,2-dodecanediol and 6.25 mmol 1,2-hexanediol. For comparison, FIG. 3A also shows an image 306 representing quantum dot structures resulting from a 90-minute reaction to also grow CdS rods over CdSe cores, where such reaction does not substitute native water with an alternative chemical compound. As compared to images 300, 302, 304, the quantum dot structures shown in image 306 are relatively stunted or otherwise small.

FIG. 3B similarly shows TEM images 310, 312, 314, 316 which variously represent quantum dot structures each formed by a respective chemical reaction according to a corresponding embodiment. Images 310, 312, 314, 316 each show a result of a corresponding 90-minute reaction to grow CdS rods over CdSe cores, where such growth is in the presence of 1-octadecanol. More particularly, the chemical reactions corresponding to image 310, 312, 314, 316 use, respectively, 3.75 mmol 1-octadecanol, 5 mmol 1-octadecanol, 7.5 mmol 1-octadecanol and 10 mmol 1-octadecanol. As shown in images 310, 312, 314, 316, higher concentrations of 1-octadecanol may result in quantum dots having geometries which are relatively more teardrop shaped.

FIG. 3C similarly shows TEM images 320, 322, 324, 326 which variously represent quantum dot structures each formed by a respective chemical reaction according to a corresponding embodiment. Images 320, 322, 324, 326 each show a result of a corresponding 45-minute reaction to grow alloyed II-VI rods over alloyed II-VI cores, where such growth is in the presence of 1,2-dodecanediol. More particularly, the chemical reactions corresponding to image 320, 322, 324, 326 use, respectively, 2.5 mmol 1,2-dodecanediol, 3.75 mmol 1,2-dodecanediol, 5 mmol 1,2-dodecanediol and 7.5 mmol 1,2-dodecanediol. As shown in images 320, 322, 324, 326, higher concentrations of 1,2-dodecanediol may result in quantum dots having geometries which are relatively short and wide, with ends that have a more squared-off shape.

FIG. 3D similarly shows TEM images 330, 332, 334, 336, 338 which variously represent quantum dot structures each formed by a respective chemical reaction according to a corresponding embodiment. Images 330, 332, 334, 336, 338 each show a result of a corresponding 45-minute reaction to grow alloyed II-VI rods over alloyed II-VI cores, where such growth is in the presence of 1-octadecanol. More particularly, the chemical reactions corresponding to image 330, 332, 334, 336, 338 use, respectively, 2.5 mmol 1-octadecanol, 5 mmol 1-octadecanol, 6.25 mmol 1-octadecanol, 7.5 mmol 1-octadecanol and 15 mmol 1-octadecanol. As shown in images 330, 332, 334, 336, 338, higher concentrations of 1-octadecanol may result in quantum dots having geometries which are relatively triangular in shape.

A desired final size and/or shape of quantum dots may be facilitated by a native water substitute which is selectively utilized according to implementation-specific details. For example, use of different amounts of octadecanol (for example) during the growth of the cadmium sulfide (CdS) may results in shapes ranging from a long rod to a shorter, wider bullet-shape (as shown, for example, in FIG. 3B). Use of dodecanediol in different amounts may facilitate control over the length of the rod without substantially changing the width (as shown, for example, in FIG. 3C). Use of octadecanol in different amounts may contribute to in shapes varying from long skinny rods to roughly triangular shaped materials (as shown, for example, in FIG. 3D).

One or more aspects of QD growth (e.g., QD shape, QD growth rate) may depend on the particular chemical compound which is to substitute native water, a concentration of the chemical compound, when the chemical compound is introduced, a duration of reaction with the chemical compound, etc. For example, use of a substitute chemical compound may allow the controlled tuning of anisotropic II-VI rods seeded by II-VI cores, where the final particle aspect ratio can be varied between 1.1:1 to 12:1. Addition of a diol or a primary alcohol may allow QD morphologies to be controlled—e.g., where QDs are selectively formed to have any in a range of shapes including rods, nail-like structures, triangles and/or the like.

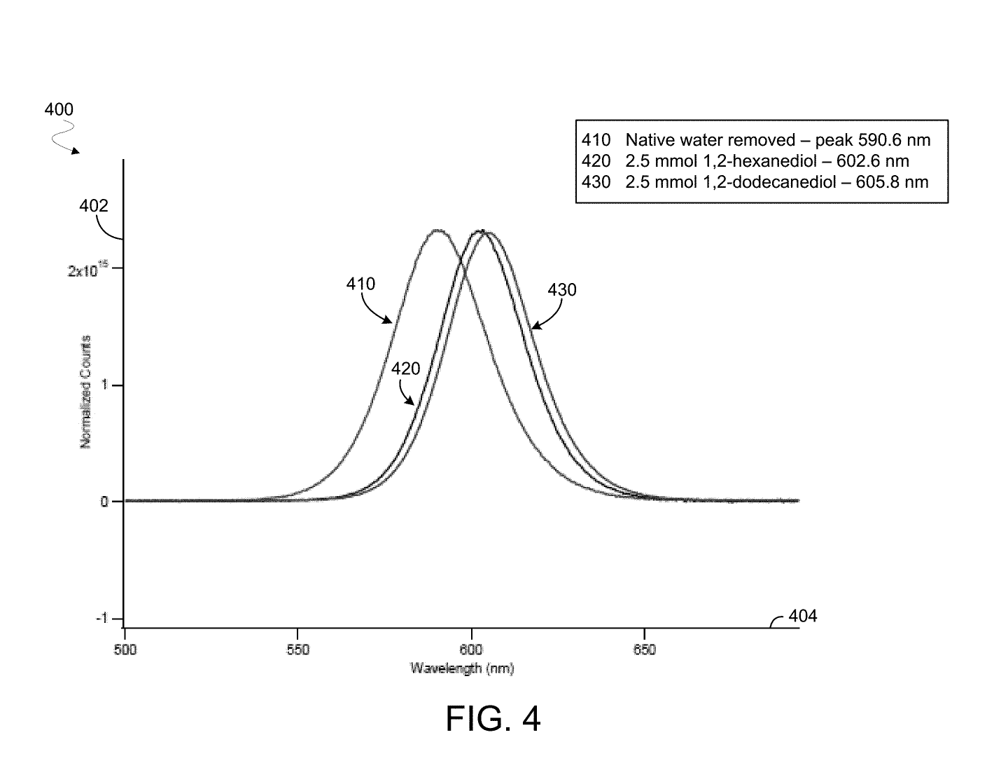

FIG. 4 shows a graph 400 including plots 410, 420, 430 of various emission spectra each for a respective one or more quantum dots. The emission characteristics of such quantum dots are variously shown in graph 400 as normalized counts (axis 402) of emitted light as a function of light wavelength (axis 404). More particularly, plot 410 corresponds to quantum dot structures formed by a chemical processes wherein native water is removed without the later addition of any chemical substitute. By contrast, plot 420 corresponds to quantum dot structures formed by chemical processes wherein native water is substituted with 2.5 mmol 1,2-hexanediol. Plot 430 corresponds to quantum dot structures formed by chemical processes wherein native water is substituted with 2.5 mmol 1,2-dodecanediol. The respective peaks of plots 410, 420, 430 are, respectively, 590.6 nanometers (nm), 602.6 nm and 605.8 nm.

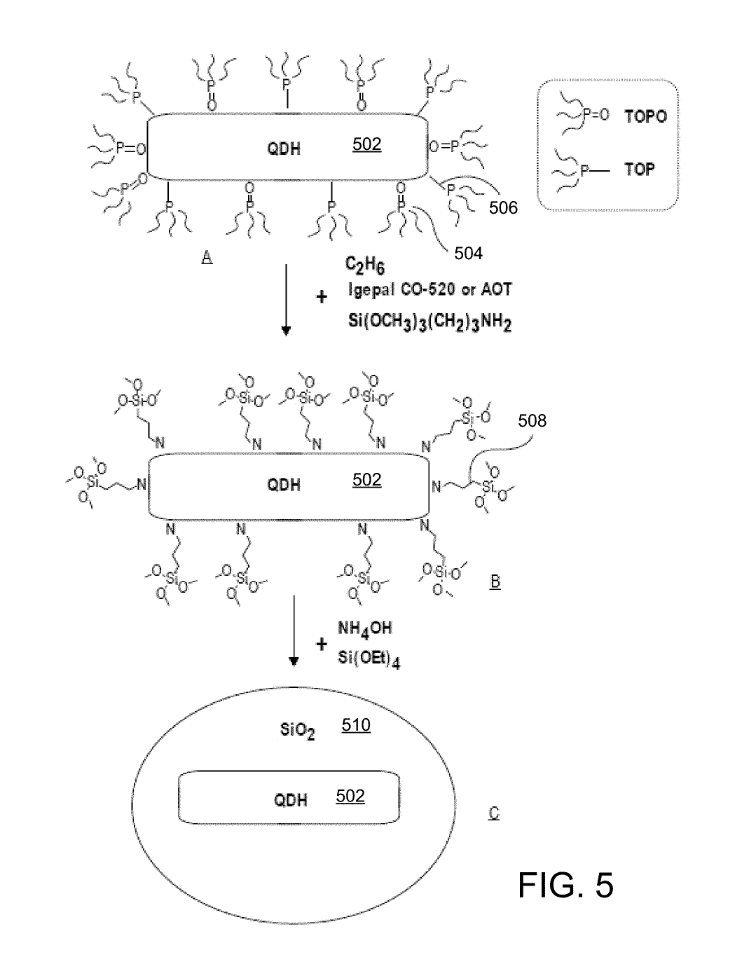

FIG. 5 illustrates operations in a reverse micelle approach to insulating a semiconductor structure (e.g., where the semiconductor structure is a quantum dot having a semiconductor coating having a geometry with squared-off ends thereon), in accordance with an embodiment. Referring to part A of FIG. 5, a quantum dot hetero-structure (QDH) 502 (e.g., a nano-crystalline core/shell pairing having a semiconductor coating having a geometry with squared-off ends thereon) has attached thereto a plurality of TOPO ligands 504 and TOP ligands 506. It is to be appreciated that other approaches may work as well, such as surface ligand exchange. For example the ligand can be selected from phosphonic acids, oleic acids, etc., before the silica is added. Referring to part B, the plurality of TOPO ligands 504 and TOP ligands 506 are exchanged with a plurality of Si(OCH₃)₃(CH₂)₃NH₂ ligands 508. The structure of part B is then reacted with TEOS (Si(OEt)₄) and ammonium hydroxide (NH₄OH) to form a silica coating 510 surrounding the QDH 502, as depicted in part C of FIG. 5. In some embodiments, native water may be removed during or after chemical processes such as that shown in FIG. 5—e.g., where, according to method 200, a chemical compound, such as a primary alcohol or a 1,2-diol, is added to facilitate control of later chemical processes (shown in, or subsequent to, that shown in FIG. 5).

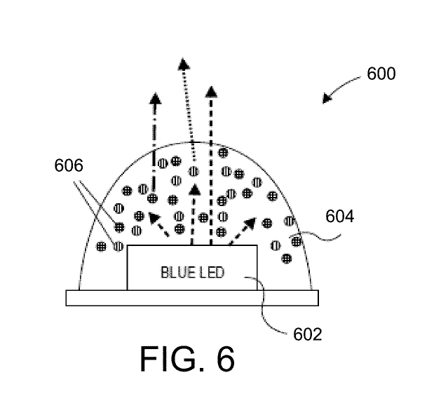

With respect to illustrating the above concepts in a resulting device configuration, FIG. 6 illustrates a lighting device 600. Device 600 has a blue LED 602 with a polymer matrix layer 604 having a dispersion of quantum dots 606 coated with a semiconductor coating having a geometry with squared-off ends therein, in accordance with one embodiment. Some or all of quantum dots 606 may have variously disposed therein or thereon residual chemical compound (e.g., including a primary alcohol or a 1,2-diol) which, for example, is an indicator of processing such as that of method 200. Devices 600 may be used to produce “cold” or “warm” white light. In one embodiment, the device 600 has little to no wasted energy since there is little to no emission in the IR regime. In a specific such embodiment, the use of a polymer matrix layer having a composition with a dispersion of anisotropic quantum dots therein enables greater than approximately 40% lm/W gains versus the use of conventional phosphors. Increased efficacy may thus be achieved, meaning increased luminous efficacy based on lumens (perceived light brightness) per watt electrical power. Accordingly, down converter efficiency and spectral overlap may be improved with the use of a dispersion of quantum dots to achieve efficiency gains in lighting and display. In an additional embodiment, a conventional phosphor is also included in the polymer matrix composition, along with the dispersion of quantum dots 606.

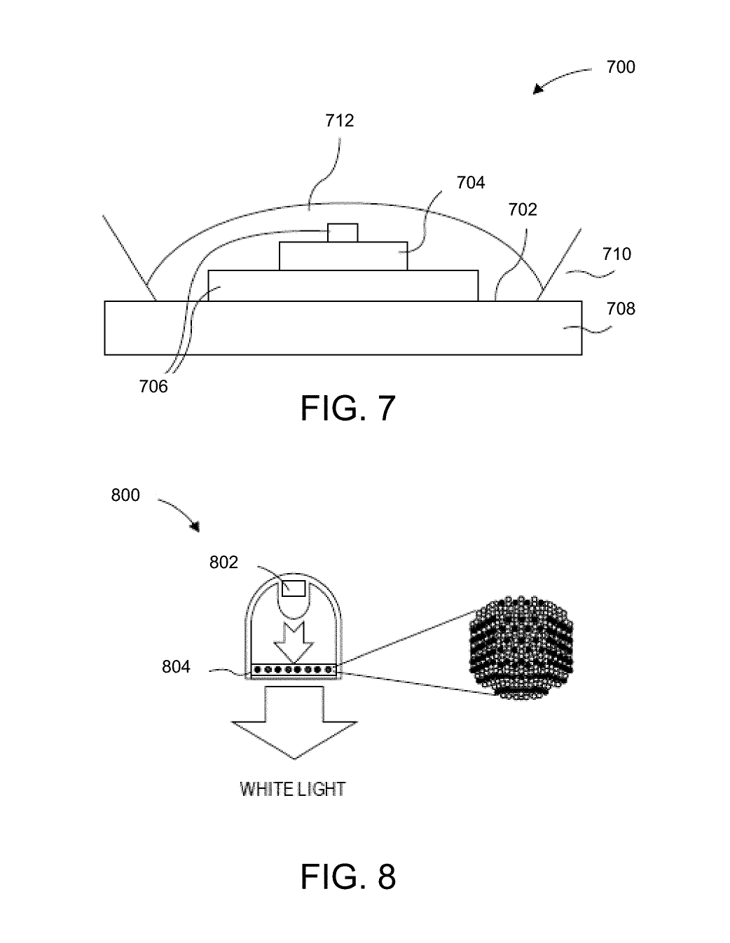

Different approaches may be used to provide a quantum dot layer in a lighting device. In an example, FIG. 7 illustrates a cross-sectional view of a lighting device 700 with a layer having a polymer matrix composition with a dispersion of quantum dots coated with a semiconductor coating having a geometry with squared-off ends therein, in accordance with an embodiment. Referring to FIG. 7, a blue LED structure 702 includes a die 704, such as an InGaN die, and electrodes 706. The blue LED structure 702 is disposed on a coating or supporting surface 708 and housed within a protective and/or reflective structure 710. A polymer matrix layer 712 is formed over the blue LED structure 702 and within the protective and/or reflective structure 710. The polymer matrix layer 712 has a composition including a dispersion of quantum dots or a combination of a dispersion of quantum dots and conventional phosphors. Some or all such quantum dots may have variously disposed therein or thereon residual chemical compound (e.g., including a primary alcohol or a 1,2-diol) which, for example, is an indicator of processing such as that of method 200. Although not depicted, the protective and/or reflective structure 710 can be extended upwards, well above the matrix layer 712, to provide a “cup” configuration.

Although described herein as applicable for on-chip applications, polymer matrix compositions may also be used as remote layers. In an example, FIG. 8 illustrates a cross-sectional view of a lighting device 800 with a polymer matrix layer having a composition with a dispersion of quantum dots coated with a semiconductor coating having a geometry with squared-off ends therein, in accordance with another embodiment.

Some or all quantum dots of lighting device 800 may have variously disposed therein or thereon residual chemical compound (e.g., including a primary alcohol or a 1,2-diol) which, for example, is an indicator of processing such as that of method 200.

Referring to FIG. 8, the lighting device 800 includes a blue LED structure 802. A quantum dot down converter screen 804 is positioned somewhat remotely from the blue LED structure 802. The quantum dot down converter screen 804 includes a polymer matrix layer with a composition having a dispersion of quantum dots therein, e.g., of varying color, or a combination of a dispersion of quantum dots and conventional phosphors. In one embodiment, the device 800 can be used to generate white light, as depicted in FIG. 8.

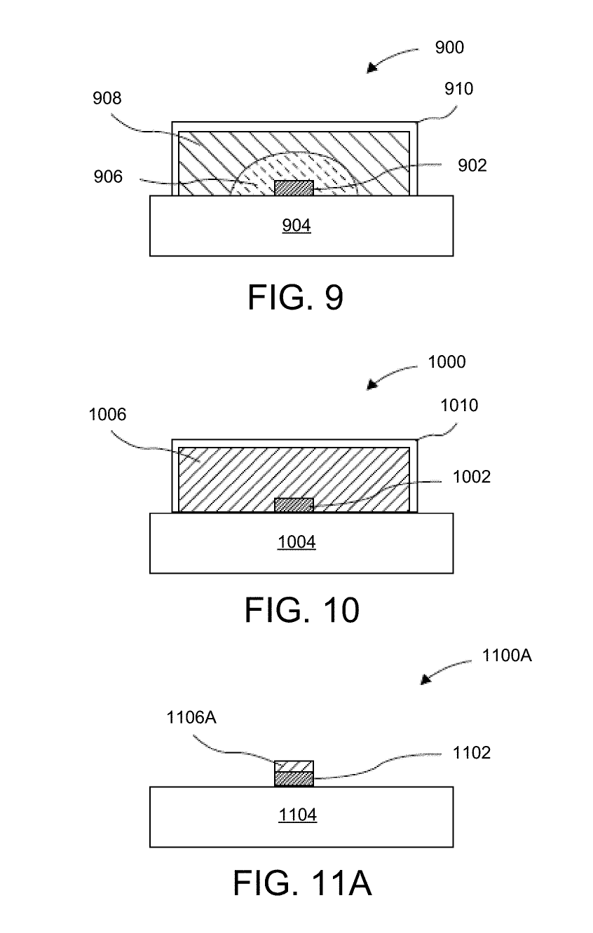

In another example, FIG. 9 illustrates a cross-sectional view of a lighting device 900 with a layer having a polymer matrix composition with a dispersion of quantum dots coated with a semiconductor coating having a geometry with squared-off ends therein, in accordance with another embodiment. Some or all quantum dots of lighting device 900 may have variously disposed therein or thereon residual chemical compound which, for example, is an indicia of processing such as that of method 200.

Referring to FIG. 9, the lighting device 900 includes a blue LED structure 902 supported on a substrate 904 which may house a portion of the electrical components of the blue LED structure 902. A first conversion layer 906 has a polymer matrix composition that includes a dispersion of red-light emitting anisotropic quantum dots therein. A second conversion layer 908 has a second polymer matrix composition that includes a dispersion of quantum dots or green or yellow phosphors or a combination thereof (e.g., yttrium aluminum garnet, YAG phosphors) therein. Optionally, a sealing layer 910 may be formed over the second conversion layer 908, as depicted in FIG. 9. In one embodiment, the device 900 can be used to generate white light.

In another example, FIG. 10 illustrates a cross-sectional view of a lighting device 1000 with a layer having a polymer matrix composition with a dispersion of quantum dots coated with a semiconductor coating having a geometry with squared-off ends therein, in accordance with another embodiment. Some or all quantum dots of lighting device 1000 may have variously disposed therein or thereon residual chemical compound which, for example, is an indicia of processing such as that of method 200. Referring to FIG. 10, the lighting device 1000 includes a blue LED structure 1002 supported on a substrate 1004 which may house a portion of the electrical components of the blue LED structure 1002. A single conversion layer 1006 has a polymer matrix composition that includes a dispersion of red-light emitting anisotropic quantum dots in combination with a dispersion of green quantum dots or green and/or yellow phosphors therein. Optionally, a sealing layer 1010 may be formed over the single conversion layer 1006, as depicted in FIG. 10. In one embodiment, the device 1000 can be used to generate white light.

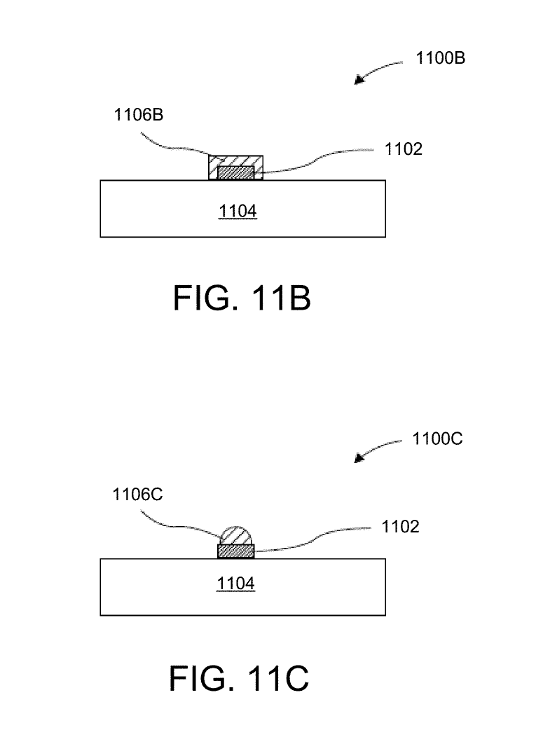

In additional examples, FIGS. 11A-11C illustrate cross-sectional views of various configurations for lighting devices 1100A-1100C with a layer having a polymer matrix composition with a dispersion of quantum dots coated with a semiconductor coating having a geometry with squared-off ends therein, respectively, in accordance with another embodiment. For a given one of lighting devices 1100A-1100C, quantum dots of the lighting device may have variously disposed therein or thereon residual chemical compound which, for example, is an indicia of processing such as that of method 200.

Referring to FIGS. 11A-11C, the lighting devices 1100A-1100C each include a blue LED structure 1102 supported on a substrate 1104 which may house a portion of the electrical components of the blue LED structure 1102. A conversion layer 1106A-1106C, respectively, has a polymer matrix composition that includes a dispersion of one or more light-emitting color types of quantum dots therein. Referring to lighting device 1100A specifically, the conversion layer 1106A is disposed as a thin layer only on the top surface of the blue LED structure 1102. Referring to lighting device 1100B specifically, the conversion layer 1106B is disposed as a thin layer conformal with all exposed surfaces of the blue LED structure 1102. Referring to lighting device 1100C specifically, the conversion layer 1106C is disposed as a “bulb” only on the top surface of the blue LED structure 1102. In the above examples (e.g., FIGS. 6-10 and 11A-11C), although use with a blue LED is emphasized, it is to be understood that a layer having a composition with a dispersion of quantum dots coated with a semiconductor coating having a geometry with squared-off ends therein can be used with other light sources as well, including LEDs other than blue LEDs.

Thus, quantum dots (QDs) and methods for efficient fabrication thereof have been disclosed.

What is claimed is:

1. A semiconductor structure, comprising:
a quantum dot including;
a first portion;
a second portion disposed on the first portion, wherein an amount of a residue disposed in or on the second portion is at least 10 parts per million (ppm), wherein the residue is a primary alcohol, a 1,2-diol or a product of a chemical reaction involving the primary alcohol or the 1,2-diol.

2. The semiconductor structure of claim 1, wherein any amount of the residue in the first portion is less than the amount of the residue disposed in or on the second portion.

3. The semiconductor structure of claim 1, wherein the residue is 1,2-hexanediol.

4. The semiconductor structure of claim 1, wherein the residue is 1,2-dodecanediol.

5. The semiconductor structure of claim 1, wherein the residue is 1-octadecanol.

6. The semiconductor structure of claim 1, wherein the quantum dot comprises a shell including cadmium sulfide (CdS) and a core including cadmium selenide (CdSe).

7. The semiconductor structure of claim 1, wherein the quantum dot includes a II-VI semiconductor compound, a III-V semiconductor compound, a IV-IV semiconductor compound or a semiconductor compound.

8. The semiconductor structure of claim 1, wherein the quantum dot includes a seed and a shell each including a respective II-VI semiconductor compound.

9. A method comprising:
performing a first reaction to dissolve a precursor of a semiconductor material, wherein a by-product of the first reaction includes water;
removing the water from a product of the first reaction;
after removing the water, combining a chemical compound with the product of the first reaction, wherein the chemical compound is a primary alcohol or a 1,2-diole including six or more carbon atoms; and
performing a second reaction with the chemical compound and the product of the first reaction to form a portion of a quantum dot.

10. The method of claim 9, wherein the chemical compound is 1,2-hexanediol.

11. The method of claim 9, wherein the chemical compound is 1,2-dodecanediol.

12. The method of claim 9, wherein the chemical compound is 1-octadecanol.

13. The method of claim 9, wherein the quantum dot comprises a shell including cadmium sulfide (CdS) and a core including cadmium selenide (CdSe).

14. The method of claim 9, wherein the quantum dot includes a II-VI semiconductor compound, a III-V semiconductor compound, a IV-IV semiconductor compound or a semiconductor compound.

15. The method of claim 9, wherein the quantum dot includes a seed and a shell each including a respective II-VI semiconductor compound.

16. A lighting apparatus, comprising:
a housing structure;
a light emitting diode supported within the housing structure; and
a light conversion layer disposed above the light emitting diode, the light conversion layer comprising a plurality of quantum dots, each quantum dot of the plurality of dots comprising:
a first portion;
a second portion disposed on the first portion, wherein an amount of a residue disposed in or on the second portion is at least 10 parts per million (ppm), wherein the residue is a primary alcohol, a 1,2-diol or a product of a chemical reaction involving the primary alcohol or the 1,2-diol.

17. The lighting apparatus of claim 16, wherein any amount of the residue in the first portion is less than the amount of the residue disposed in or on the second portion.

18. The lighting apparatus of claim 16, wherein the chemical compound is 1,2-hexanediol.

19. The lighting apparatus of claim 16, wherein the chemical compound is 1,2-dodecanediol.

20. The lighting apparatus of claim 16, wherein the chemical compound is 1-octadecanol.

21. The lighting apparatus of claim 16, wherein each quantum dot of the plurality of dots comprises a shell including cadmium sulfide (CdS) and a core including cadmium selenide (CdSe).

22. The lighting apparatus of claim 16, wherein each quantum dot of the plurality of dots includes a II-VI semiconductor compound, a III-V semiconductor compound, a IV-IV semiconductor compound or a semiconductor compound.

23. The lighting apparatus of claim 16, wherein each quantum dot of the plurality of dots includes a seed and a shell each including a respective II-VI semiconductor compound.
